(19) United States
(12) Patent Application Publication
(10) Pub. No.: US 2012/0217977 A1
(43) Pub. Date: Aug. 30, 2012

(54) TEST APPARATUS FOR PCI-E SIGNALS

(75) Inventors: FENG-JUAN GAO, Shenzhen City (CN); HUI LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/043,627

(22) Filed: Mar. 9, 2011

(30) Foreign Application Priority Data
Feb. 25, 2011 (CN) 201110045772.3

(51) Int. Cl. G01R 31/02

(52) U.S. Cl. 324/543

(57) ABSTRACT

A test apparatus includes a sending chip, a receiving chip, first and second peripheral component interconnect express (PCI-E) buses between the sending and receiving chips, first to fourth pads, and first and second terminal resistors. Each pad includes first and second areas laid with copper and a void third area between the first and second areas. The first and second areas of the first and second pads are connected to the first and second PCI-E buses. The first areas of the third and fourth pads are connected to the first and second PCI-E buses. A first end of the first terminal resistor is connected to the second area of the third pad, a second end of the first terminal resistor is grounded. A first end of the second terminal resistors is connected to the second area of the fourth pad, a second end of the second terminal resistor is grounded.

### BACKGROUND

1. Technical Field

The present disclosure relates to test apparatus, and particularly relates to a test apparatus for testing peripheral component interconnect express (PCI-E) signals.

2. Description of Related Art

PCI-E types of buses for computers have been used widely, for example, a south bridge chip communicates with a network chip through a PCI-E bus. Impedance changes, signal interference, electro magnetic interference (EMI), and other factors may influence PCI-E bus signal transmission, so it is necessary to test signal transmission performance of the PCI-E bus.

However, many receiving chips and sending chips use fine-pitch ball grid array (FBGA) packaging, which may obstruct access to test points on the PCI-E bus, making it difficult for testing tools such as oscilloscope probes to test the signal transmission performance of the PCI-E bus. Furthermore, using the probes on the test points may cause signal reflection. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of a test apparatus, including a pad, in accordance with an exemplary embodiment of the present disclosure.

FIG. 2 is an enlarged view of the pad of FIG. 1.

FIG. 3 is a wave diagram of testing PCI-E signals using the test apparatus of FIG. 1.

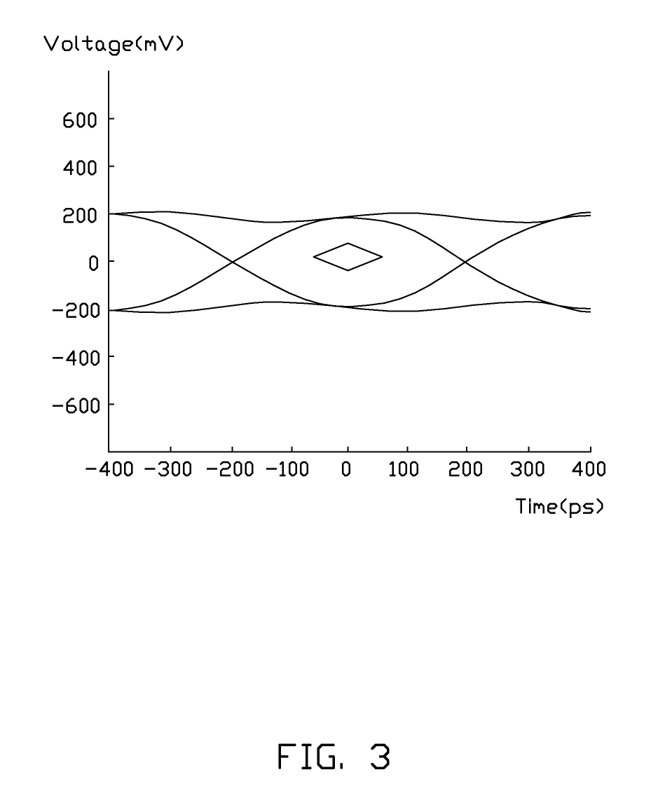

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

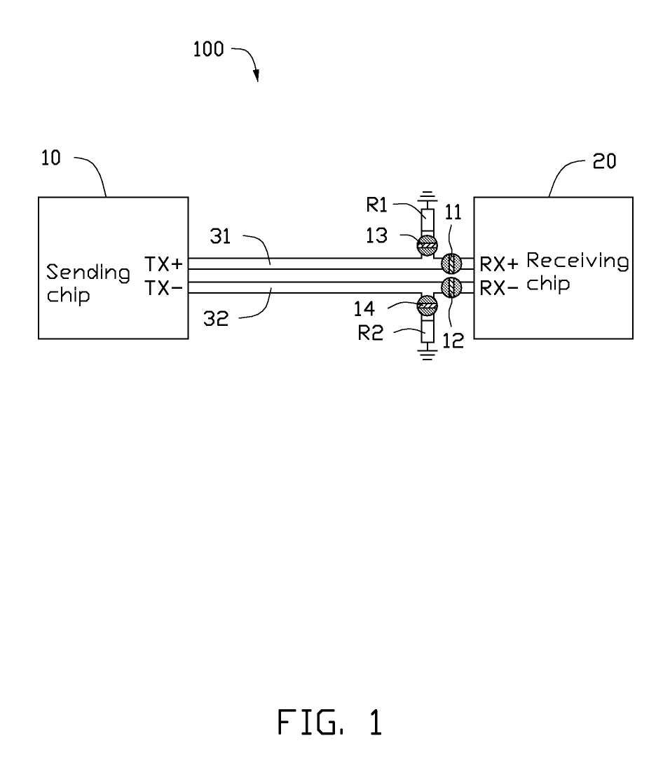

Referring to FIG. 1, a test apparatus 100 is set on a motherboard (not shown) for testing PCI-E signals of the motherboard. The test apparatus 100 in accordance with an exemplary embodiment includes a sending chip 10, a receiving chip 20, two peripheral component interconnect express (PCI-E) buses 31 and 32 connected between the sending chip 10 and the receiving chip 20, first to fourth pads 11-14, and two terminal resistors R1 and R2. The first pad 11 is set on the PCI-E bus 31 and adjacent to the receiving chip 20. The second pad 12 is set on the PCI-E bus 32 and adjacent to the receiving chip 20. A first end of the third pad 13 is connected to the first PCI-E bus 31, and a second end of the third pad 13 is connected to a first end of the terminal resistor R1. A second end of the terminal resistor R1 is grounded. A first end of the fourth pad 14 is connected to the second PCI-E bus 32, and a second end of the fourth pad 14 is connected to a first end of the terminal resistor R2. A second end of the terminal resistor R2 is grounded.

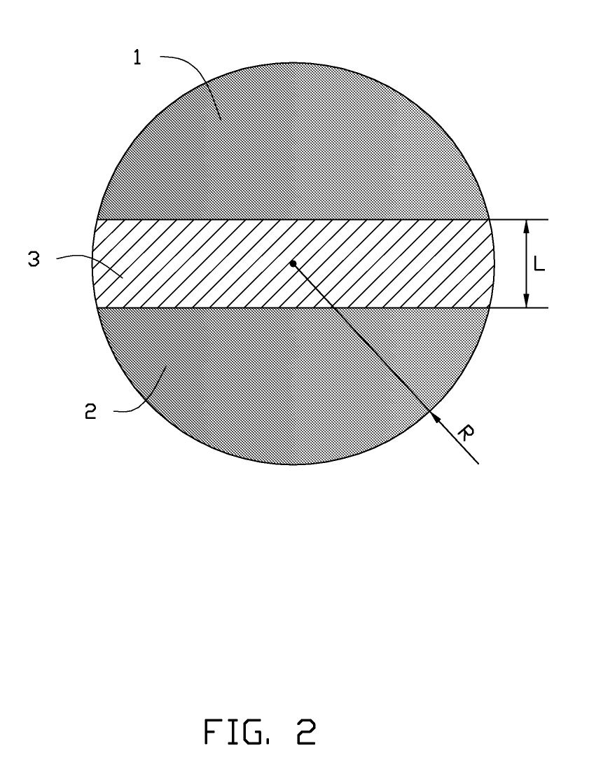

Referring to FIG. 2, each of the first to the fourth pads 11-14 is substantially circular, and a radius R of each pad is about 5 mils. Each pad includes first to third areas 1-3. The third area 3 extends through the pad, between the first and second areas 1 and 2. The first and the second areas 1 and 2 are laid with copper, and the third area 3 is a void area separating the first area 1 from the second area 2. The third area 3 is substantially strip-shaped and a width L of the void area is about 4 mils. The first and the second areas 1 and 2 of the first pad 11 are respectively connected to the PCI-E bus 31. The first and the second areas 1 and 2 of the second pad 12 are respectively connected to the PCI-E bus 32. The first area 1 of the third pad 13 is connected to the first PCI-E bus 31. The second area 2 of the third pad 13 is connected to the terminal resistor R1. The first area 1 of the fourth pad 14 is connected to the second PCI-E bus 32. The second area 2 of the fourth pad 14 is connected to the terminal resistor R2.

A width of each of the PCI-E buses 31 and 32 is about 5 mils. An oscilloscope with two probes (not shown), such as a Tektronix P7313 oscilloscope, can be easily used to test the PCI-E signals from the PCI-E buses 31 and 32, because the diameter of the probe is about 10 mils, as are the diameters of the first to the fourth pads 11-14. In other embodiments, the width L of the third area 3 of each of the first to the fourth pads 11-14 can be less than 10 mils, so that if the 10 mil probe contacts the third area 3, it will also contact the first area 1 and the second area 2, allowing the receiving chip 20 to receive PCI-E signals from the sending chip 10 through the PCI-E buses 31 and 32.

In one embodiment, resistances of the terminal resistors R1 and R2 are about 50 ohms.

In test, the probes of the oscilloscope are placed on the third areas 3 of the first and the second pads 11 and 12, to connect the first and the second areas 1 and 2 of the first pad 11 to each other and connect the first and the second areas 1 and 2 of the second pad 12 to each other. The sending chip 10 sends PCI-E signals to the receiving chip 20 for powering on the motherboard. The probes of the oscilloscope are respectively connected to the third pad 13 and the fourth pad 14 for capturing the PCI-E signals. The captured PCI-E signals can then be displayed by the oscilloscope and analyzed.

The test apparatus 100 includes pads and terminal resistors on the PCI-E bus for convenient testing of PCI-E signals and avoiding signal reflection during testing.

It is to be understood, however, that even though numerous characteristics and advantages of the disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A test apparatus to test peripheral component interconnect express (PCI-E) signals, the test apparatus comprising:
a sending chip to send the PCI-E signals;
a receiving chip to receive the PCI-E signals from the sending chip;
a first PCI-E bus connected between the sending chip and the receiving chip;
a second PCI-E bus connected between the sending chip and the receiving chip;
first to fourth pads, each of the first to fourth pads comprising first to third areas, wherein the first and the second areas are laid with copper, the third area is a void area and extends through the pad, between the first and second areas for separating the first area from the second area, the first and the second areas of the first pad are connected to the first PCI-E bus, the first and the second areas of the second pad are connected to the second PCI-E bus, the first area of the third pad is connected to the first PCI-E bus, the first area of the fourth pad is connected to the second PCI-E bus;
a first terminal resistor comprising a first end connected to the second area of the third pad and a second end grounded; and
a second terminal resistors comprising a first end connected to the second area of the fourth pad and a second end grounded.

2. The test apparatus as claimed in claim 1, wherein each of the first to the fourth pads is substantially circular, and a radius of each pad is about 5 mils; the third area of each pad is a substantially strip-shaped void area, and a width of the third area is about 4 mils.

3. The test apparatus as claimed in claim 1, wherein resistances of the first and the second terminal resistors are about 50 ohms.
